(19) United States
(12) Patent Application Publication
(10) Pub. No.: US 2019/0348060 A1
(43) Pub. Date: Nov. 14, 2019

(54) APPARATUS AND METHOD FOR ENHANCING A WANTED COMPONENT IN A SIGNAL

(71) Applicant: Huawei Technologies Co., Ltd., Shenzhen (CN)

(72) Inventors: Wei Xiao, Shenzhen (CN); Wenyu Jin, Shenzhen (CN)

(21) Appl. No.: 16/520,050

(22) Filed: Jul. 23, 2019

Related U.S. Application Data
(63) Continuation of application No. PCT/EP2017/051311, filed on Jan. 23, 2017.

(51) Int. Cl. G10L 21/0364; G10L 21/0208; G10L 21/034; G10L 21/0332; G10L 21/02; H03G 3/32

(52) U.S. Cl. CPC G10L 21/0364; G10L 21/0208; H03G 3/32; G10L 21/0332; G10L 21/0205; G10L 21/034

(57) ABSTRACT

A signal enhancer is provided and comprises an input configured to receive an audio signal that has a wanted component and an unwanted component, and a perception analyser that is configured to split the audio signal into a plurality of spectral components. The perception analyser is configured to, for each spectral component, designate that spectral component as belonging to the wanted component or the unwanted component in dependence on a power estimate associated with that spectral component. If a spectral component is designated as belonging to the unwanted component, the perception analyser is configured to adjust its power by applying an adaptive gain to that spectral component, wherein the adaptive gain is selected in dependence on how perceptible the spectral component is expected to be to a user. The signal enhancer improves the intelligibility of the wanted component.

### CROSS-REFERENCE TO RELATED APPLICATIONS

This application is a continuation of International Application No. PCT/EP2017/051311, filed on Jan. 23, 2017, the disclosure of which is hereby incorporated by reference in its entirety.

### TECHNICAL FIELD

Embodiments of this disclosure relate to an apparatus and method for enhancing a signal that has a component that is wanted and a component that is unwanted.

### BACKGROUND

It can be helpful to enhance a speech component in a noisy signal. For example, speech enhancement is desirable to improve the subjective quality of voice communication, e.g., over a telecommunications network. Another example is automatic speech recognition (ASR). If the use of ASR is to be extended, it needs to improve its robustness to noisy conditions. Some commercial ASR solutions claim to offer good performance, e.g., a word error rate (WER) of less than 10%. However, this performance is often only realisable under good conditions, with little noise. The WER can be larger than 40% under complex noise conditions.

One approach to enhance speech is to capture the audio signal with multiple microphones and filter those signals with an optimum filter. The optimum filter is typically an adaptive filter that is subject to certain constraints, such as maximising the signal-to-noise ratio (SNR). This technique is based primarily on noise control and gives little consideration to auditory perception. It is not robust under high noise levels. Too strong processing can also attenuate the speech component, resulting in poor ASR performance.

Another approach is based primarily on control of the foreground speech, as speech components tend to have distinctive features compared to noise. This approach increases the power difference between speech and noise using the so-called “masking effect”. According to psychoacoustics, if the power difference between two signal components is large enough, the masker (with higher power) will mask the maskee (with lower power) so that the maskee is no longer audibly perceptible. The resulting signal is an enhanced signal with higher intelligibility.

A technique that makes use of the masking effect is Computational Auditory Scene Analysis (CASA). It works by detecting the speech component and the noise component in a signal and masking the noise component. One example of a specific CASA method is described in CN105096961. An overview is shown in FIG. 1. In this technique, one of a set of multiple microphone signals is selected as a primary channel and processed to generate a target signal. This target signal is then used to define the constraint for an optimal filter to generate an enhanced speech signal. This technique makes use of a binary mask, which is generated by setting time and frequency bins in the primary signal's spectrum that are below a reference power to zero and bins above the reference power to one. This is a simple technique and, although the Chinese Patent No. CN105096961 (Xiaohong Yang et al, patented on Feb. 1, 2019) proposes some additional processing, the target signal generated by this method generally has many spectrum holes. The additional processing also introduces some undesirable complexity into the technique, including the need for two time-frequency transforms and their inverses.

### SUMMARY

It is an object of the disclosure to provide improved concepts for enhancing a wanted component in a signal.

The foregoing and other objects are achieved by the features of the independent claims. Further implementation forms are apparent from the dependent claims, the description and the figures.

According to a first aspect, a signal enhancer is provided that comprises an input configured to receive an audio signal that has a wanted component and an unwanted component. It also comprises a perception analyser that is configured to split the audio signal into a plurality of spectral components. The perception analyser is also configured to, for each spectral component, designate that spectral component as belonging to the wanted component or the unwanted component in dependence on a power estimate associated with that spectral component. If a spectral component is designated as belonging to the unwanted component, the perception analyser is configured to adjust its power by applying an adaptive gain to that spectral component, wherein the adaptive gain is selected in dependence on how perceptible the spectral component is expected to be to a user. This improves the intelligibility of the wanted component.

In a first implementation form of the first aspect, the perceptual analyser may be configured to, for each spectral component that is designated as belonging to the unwanted component, compare its power estimate with a power threshold. The perceptual analyser may be configured to select the adaptive gain to be a gain that will leave the power associated with that spectral component unchanged if the power estimate is below the power threshold. The perceptual analyser may be configured to select the adaptive gain to be a gain that will reduce the power associated with that spectral component if the power estimate is above the power threshold. This increases the relative power of the wanted component relative to the unwanted component, which improves the intelligibility of the wanted component.

In a second implementation form of the first aspect, the power threshold of the first implementation form may be selected in dependence on a power at which that spectral component is expected to become perceptible to the user. This improves the intelligibility of the wanted component in a practical sense, since different frequency components are perceived differently by a human user.

In a third implementation form of the first aspect, the power threshold of the first or second implementation forms may be selected in dependence on how perceptible a spectral component is expected to be to a user given a power associated with one or more of the other spectral components. This improves the perceptibility of the wanted component in the enhanced signal.

In a fourth implementation form of the first aspect, the perception analyser of any of the first to third implementation forms may be configured to select the power threshold for each spectral component in dependence on a group associated with that spectral component, wherein the same power threshold is applied to the power estimates for all the spectral components comprised in a specific group. This is consistent with the principles of psychoacoustics.

In a fifth implementation form of the first aspect, the perception analyser of the fourth implementation form may be configured to select the power threshold for each group of spectral components to be a predetermined threshold that is assigned to that specific group in dependence on one or more frequencies that are represented by the spectral components in that group. This is consistent with the principles of psychoacoustics.

In a sixth implementation form of the first aspect, the perception analyser of the fourth or fifth implementation forms may be configured to determine the power threshold for a group of spectral components in dependence on the power estimates for the spectral components in that specific group. This considers the relative strength, in the signal, of spectral components that are similarly perceptible to a human user.

In a seventh implementation form of the first aspect, the perception analyser of the sixth implementation form may be configured to determine the power threshold for a specific group of spectral components by identifying the highest power estimated for a spectral component in that specific group and generating the power threshold by decrementing that highest power by a predetermined amount. This considers how perceptible a particular spectral component is likely to be given the power of other spectral components in its spectral group.

In an eighth implementation form of the first aspect, the perception analyser of any of the fourth to seventh implementation forms may be configured to select the power threshold for a group of spectral components by comparing a first threshold and a second threshold. The first threshold may be assigned to a specific group in dependence on one or more frequencies that are represented by the spectral components in that group. The second threshold may be determined in dependence on the power estimates for the spectral components in that group. The perception analyser may be configured to select, as the power threshold for the group, the lower of the first and second thresholds. The signal enhancer is thus able to select the more appropriate threshold.

In a ninth implementation form of the first aspect, the perception analyser of any of the first to eighth implementation forms may be configured to, for each spectral component that is designated as: (i) belonging to the unwanted component; and (ii) having a power estimate that is above the power threshold, select the adaptive gain to be a ratio between the power threshold and the power estimate for that spectral component. This reduces the power of the unwanted spectral component to an acceptable level.

In a tenth implementation form of the first aspect, the signal enhancer, in particular the signal enhancer of any of the above-mentioned implementation forms, comprises a transform unit. The transform unit may be configured to receive the audio signal in the time domain and convert that signal into the frequency domain, whereby the frequency domain version of the audio signal represents each spectral component of the audio signal by a respective coefficient. The perception analyser may be configured to adjust the power associated with a spectral component by applying the adaptive gain to the coefficient that represents that spectral component in the frequency domain version of the audio signal. Performing this adjustment in the frequency domain is convenient, because it is in the frequency domain that the perceptual differences between different parts of the audio signal become apparent.

In an eleventh implementation form of the first aspect, the perception analyser of the tenth implementation form may be configured to form a target audio signal to comprise non-adjusted coefficients, which represent the spectral components designated as belonging to the wanted component of the audio signal, and adjusted coefficients, which represent the spectral components designated as belonging to the unwanted component of the audio signal. This target audio signal can form a constraint for optimising the filtering of the audio signal and other audio signals. The target audio signal could be formed in the frequency domain or in the time domain.

In a twelfth implementation form of the first aspect, the transform unit of a signal enhancer of the eleventh aspect may be configured to receive the target audio signal in the frequency domain convert it into the time domain, wherein the output is configured to output the time domain version of the target audio signal. This generates a time domain signal that can be used as a target audio signal.

According to a second aspect, a method is provided that comprises obtaining an audio signal that has a wanted component and an unwanted component. The method comprises splitting the audio signal into a plurality of spectral components. It also comprises, for each spectral component, designating that spectral component as belonging to the wanted component or the unwanted component in dependence on a power estimate associated with that spectral component. The method comprises, if a spectral component is designated as belonging to the unwanted component, adjusting its power by applying an adaptive gain to that spectral component, wherein the adaptive gain is selected in dependence on how perceptible the spectral component is expected to be to a user.

According to a third aspect, a non-transitory machine readable storage medium is provided having stored thereon processor executable instructions implementing a method. That method comprises obtaining an audio signal that has a wanted component and an unwanted component. It also comprises, for each spectral component, designating that spectral component as belonging to the wanted component or the unwanted component in dependence on a power estimate associated with that spectral component. The method comprises, if a spectral component is designated as belonging to the unwanted component, adjusting its power by applying an adaptive gain to that spectral component, wherein the adaptive gain is selected in dependence on how perceptible the spectral component is expected to be to a user.

### BRIEF DESCRIPTION OF DRAWINGS

These and other aspects will now be described by way of example with reference to the accompanying drawings. In the drawings:

FIG. 1 relates to a prior art technique for enhancing speech signals;

FIG. 2 shows an example of a signal enhancer according to an embodiment;

FIG. 3 shows an example of a process for enhancing a signal according to an embodiment;

FIG. 4 shows a more detailed example of a process for enhancing a signal;

FIGS. 5a to c show processes for enhancing a signal according to embodiments in that use different final power thresholds for setting the adaptive gain;

FIG. 6 shows absolute hearing thresholds for different bark bands;

FIG. 7 shows how techniques according to one or more embodiments affect the relative power of wanted and unwanted signal components; and

FIGS. 8a and b show examples of speech processing systems that are configured to receive input signals from two microphones.

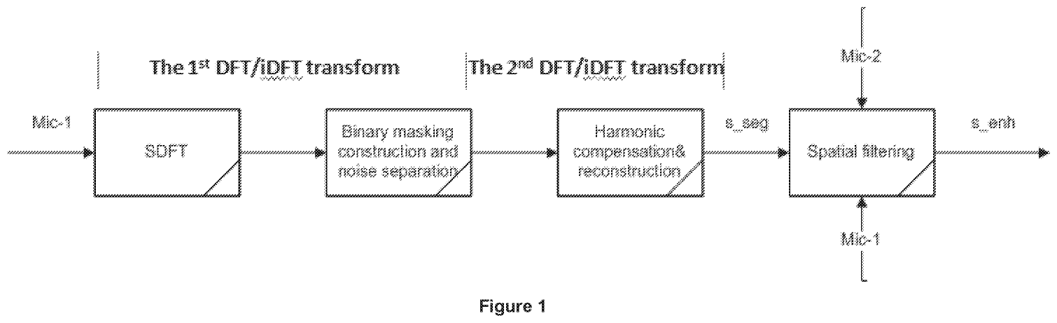

### DESCRIPTION OF EMBODIMENTS

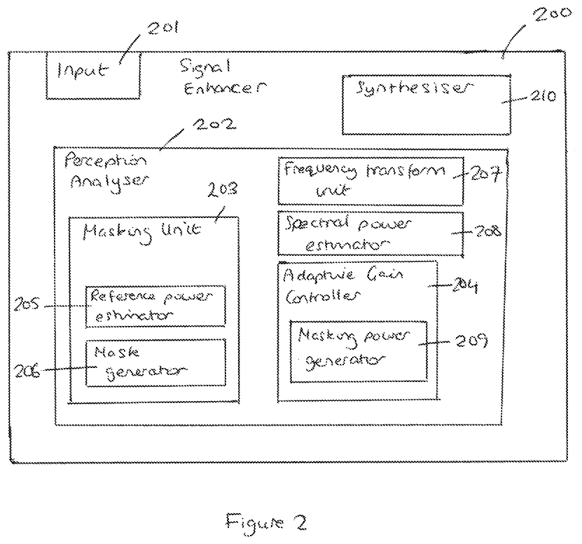

A signal enhancer is shown in FIG. 2. The signal enhancer, shown generally at 200, comprises an input 201 and a perception analyser 202. The input is configured to receive a signal. The signal includes a component that is wanted and a component that is unwanted. In many embodiments, the signal will be an audio signal that represents sound captured by a microphone. The wanted component will usually be speech. The unwanted component will usually be noise. If a microphone is in an environment that includes speech and noise, it will typically capture an audio signal that is representative of both. The wanted and unwanted components are not limited to being speech or noise, however. They could be of any type of signal.

The perception analyser 202 comprises a frequency transform unit 207 that is configured to split the input signal into a plurality of spectral components. Each spectral component represents part of the input signal in a particular frequency band or bin. The perception analyser also includes a masking unit 203 that is configured to analyse each spectral component and designate it as being part of the wanted component or part of the unwanted component. The masking unit makes this decision in dependence on a power estimate that is associated with the spectral component. The perception analyser also includes an adaptive gain controller 204. If a spectral component is designated as being part of the unwanted component, the adaptive gain controller applies an adaptive gain to that spectral component. The adaptive gain is selected in dependence on how perceptible the spectral component is expected to be to a user.

The signal enhancer shown in FIG. 2 also comprises a synthesiser 210. The synthesiser is an optional component that is configured to combine all spectral components together to form an enhanced signal, i.e. the synthesiser combines the wanted components and the adjusted unwanted components into a single output signal. The synthesiser may be configured to perform this operation in the frequency domain or in the time domain. For example, the spectral components may be converted into the time domain and then combined, or they may be combined in the frequency domain and then converted into the time domain.

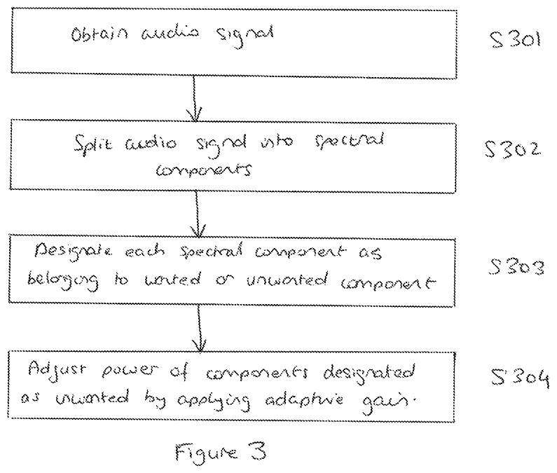

An example of a method for enhancing a signal is shown in FIG. 3. The method starts in step S301 with obtaining an audio signal that has both a wanted component and an unwanted component. This signal is then split into a plurality of spectral components in step S302. Each spectral component is then designated either as belonging to the wanted component or as belonging to the unwanted component (step S303). This designation can be made in dependence on a power estimate that is associated with each spectral component. In step S304, the power of any components that have been designated as belonging to the unwanted component is adjusted by applying an adaptive gain to that spectral component. The adaptive gain is selected in dependence on how perceptible the spectral component is expected to be to a user.

The structures shown in FIG. 2 (and all the block apparatus diagrams included herein) are intended to correspond to a number of functional blocks. This is for illustrative purposes only. FIG. 2 is not intended to define a strict division between different parts of hardware on a chip or between different programs, procedures or functions in software. In some embodiments, some or all of the signal processing techniques described herein are likely to be performed wholly or partly in hardware. This particularly applies to techniques incorporating repetitive operations such as Fourier transforms and threshold comparisons. In some implementations, at least some of the functional blocks are likely to be implemented wholly or partly by a processor acting under software control. Any such software is suitably stored on a non-transitory machine readable storage medium. The processor could, for example, be a DSP of a mobile phone, smart phone, tablet or any generic user equipment or generic computing device.

The apparatus and method described herein can be used to implement speech enhancement in a system that uses signals from any number of microphones. In one example, the techniques described herein can be incorporated in a multi-channel microphone array speech enhancement system that uses spatial filtering to filter multiple inputs and to produce a single-channel, enhanced output signal. The enhanced signal that results from these techniques can provide a new constraint for spatial filtering by acting as a target signal. A signal that is intended to act as a target signal is preferably generated by taking account of psychoacoustic principles. This can be achieved by using an adaptive gain control that considers the estimated perceptual thresholds of different frequency components in the frequency domain.

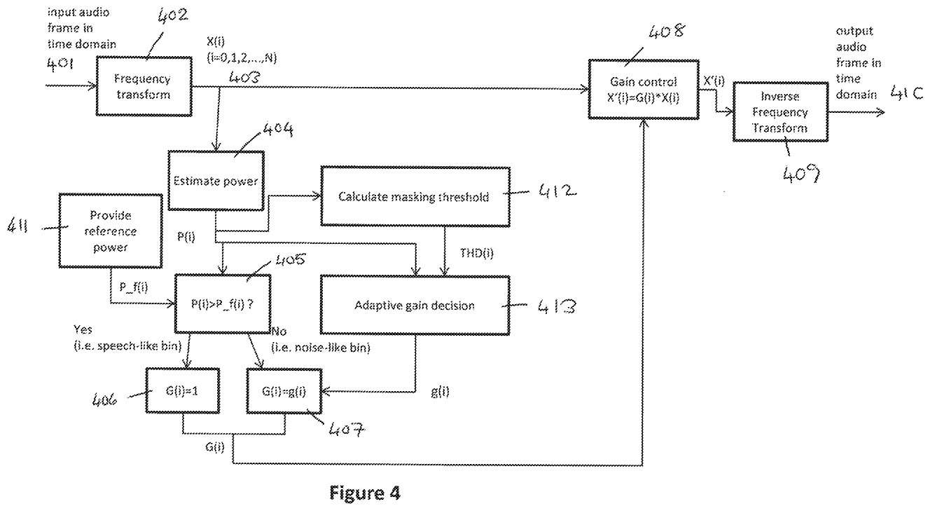

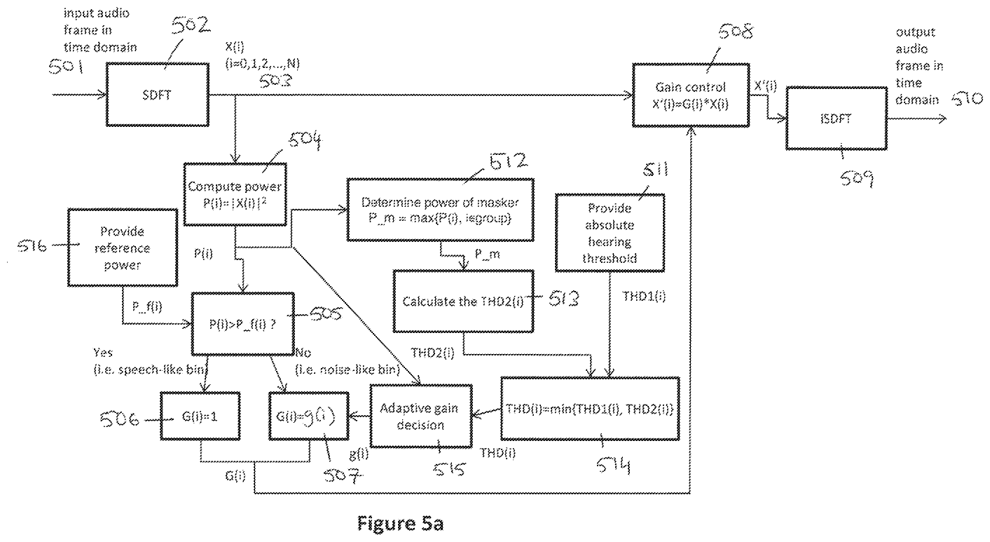

A more detailed embodiment is shown in FIG. 4. This figure gives an overview of a speech enhancement technique that is described below with reference to some of the functional blocks shown in FIG. 2. A frame of an audio signal 401 is input into the system in the time domain. For simplicity, FIG. 4 and the description below describe the processing of a single frame. This input frame is processed by a frequency transform unit 207, 402 to output a series of frequency coefficients 403. Each frequency coefficient X(i) represents the amplitude of spectral component in frequency bin i. The power associated with each of the spectral components is then estimated by spectral power estimator 208 using the coefficients 403. This estimated power is used by masking unit 203 to designate the respective spectral component either as belonging to noise and or as belonging to speech. Thus, some of the spectral components will be designated as belonging to noise and others of the spectral components as belonging to speech. In the example of FIG. 4, this is done in 405 by the mask generator 206 comparing the estimated power for each spectral component with a reference power threshold 411 (which is generated by reference power estimator 205). The reference power threshold may be set to a power level that is dependent on a power expected of the noise components in the signal. Spectral components with a higher power than this are assumed to include speech. Spectral components with a lower power are assumed to just contain noise.

The spectral components that are designated as belonging to speech are then compared with a masking power threshold 412 (which is output by masking power generator 209). This additional power threshold THD(i) relates to the power at which different spectral components are expected to become perceptible to a user. (There are various parameters that could be used to set this threshold, and some examples are described below.) The masking power threshold controls the adaptive gain decision 413 that is made by the adaptive gain controller 204. The gain g(i) that is applied by the controller to the spectral component in bin i if that spectral component has been designated as noise changes in dependence on whether that spectral component meets the masking power threshold or not (in 407). In one example, the power of a spectral component is left unchanged if its power estimate is below the masking power threshold and is reduced if its power estimate is above the masking power threshold. Spectral components that have been designated as including speech are to be left unchanged, so a gain of one is selected for them in 406. This is just an example as any suitable gain could be applied. For example, in one example the spectral components that are designated as including speech could be amplified.

The gain selected for each spectral component is applied to each respective coefficient 408. The new coefficients X′(i) form the basis for an inverse frequency transform 409 to construct an output frame in the time domain 410.

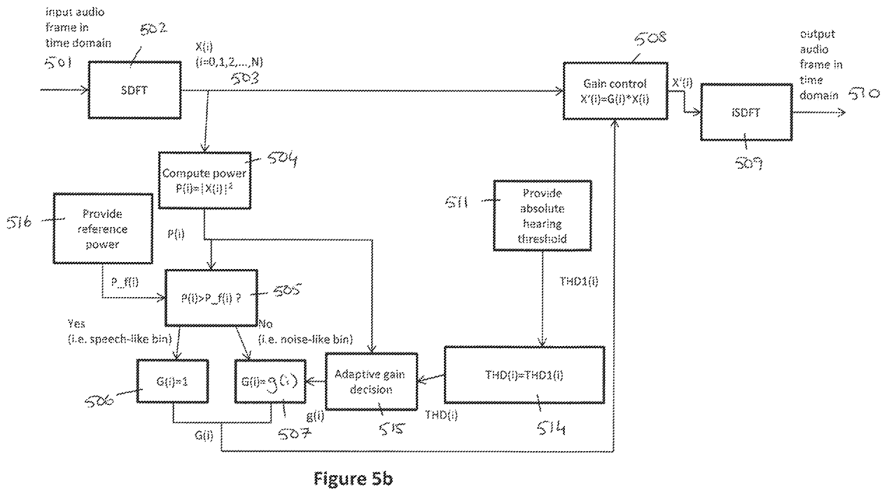

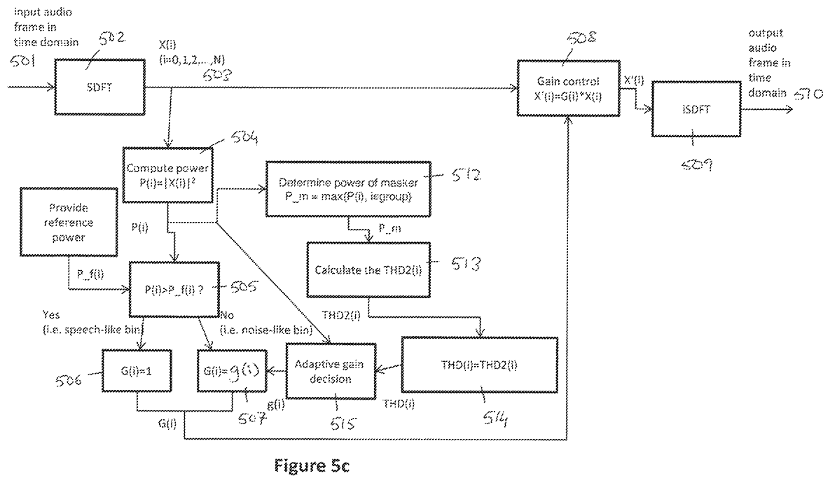

FIG. 5a shows a similar process to that outlined in FIG. 4. FIG. 5a includes specific examples of how particular steps in the process could be performed. These specific examples could also be used for equivalent steps in processes that may differ from that shown in FIG. 5a when considered overall. For example, FIG. 5a illustrates an overall process in which the masking power threshold is selected from two options, THD1 and THD2. This does not mean that all the example steps described below are limited to embodiments in which the masking power threshold is selected from THD1 and THD2, however. For example, FIG. 5a includes an example of how to estimate the power for each spectral component. This example is generally applicable, and could readily be incorporated within an overall process in which the masking threshold is selected in a different way from that shown in FIG. 5a.

In FIG. 5a the incoming signals are again processed in frames. This achieves real-time processing of the signals. Each incoming signal may be divided into a plurality of frames with a fixed frame length (e.g., 16 ms). The same processing is applied to all frames. The single channel input 501 may be termed “Mic-1”. This input may be one of a set of microphone signals that all comprise a component that is wanted, such as speech, and a component that is unwanted, such as noise. The set of signals need not be audio signals and could be generated by methods other than being captured by a microphone.

In block 502 a time-frequency transform is performed on the audio signal received by the input to obtain its frequency spectrum. This step may be implemented by performing a Short-Time Discrete Fourier Transform (SDFT) algorithm. The SDFT is a Fourier-related transform used to determine the sinusoidal frequency and phase content of local sections of a signal as it changes over time. The SDFT may be computed by dividing the audio signal into short segments of equal length (such as a frame 501) and then computing the Fourier transform separately on each short segment. The result is the Fourier spectrum for each short segment of the audio signal, which captures the changing frequency spectra of the audio signal as a function of time. Each spectral component thus has an amplitude and a time extension.

An SDFT 502 is performed for each frame of the input signal 501. If the sampling rate is 16 kHz, the frame size might be set as 16 ms. This is just an example and other sampling rates and frame sizes could be used. It should also be noted that there is no fixed relationship between sampling rate and frame size. So, for example, the sampling rate could be 48 kHz with a frame size of 16 ms. A 512-point SDFT can be implemented over the input signal. Performing the SDFT generates a series of complex-valued coefficients X(i) in the frequency domain (where coefficient index i=0, 1, 2, 3, etc. can be used to designate the index of the signal in the time domain or the index of coefficients in the frequency domain). These coefficients are Fourier coefficients and can also be referred to as spectral coefficients or frequency coefficients.

For each coefficient X(i) a corresponding power P(i)=|X(i)|² is computed 503. This can be defined by:

P(i)=real(X(i))²+imag(X(i))²

where real(*) and imag(*) are the real part and the imaginary part of the respective SDFT coefficient.

A reference power Pf(i) is also estimated for each Fourier coefficient X(i) 516. The perceptual analyser 202 in FIG. 2 may incorporate a reference power estimator 205 for generating this estimate. Any suitable noise estimation (NE) method can be used for this estimation. A simple approach is to average the power density of each coefficient over the current frame and one or more previous frames. According to speech processing theory, this simple approach is most suitable for scenarios in which the audio signal is likely to incorporate stationary noise. Another option is to use advanced noise estimation methods, which tend to be suitable for scenarios incorporating non-stationary noise. In some embodiments, the reference power estimator may be configured to select an appropriate power estimation algorithm in dependence on an expected noise scenario, e.g., whether the noise is expected to be stationary or non-stationary in nature.

The next step is to implement binary masking by comparing the power P(i) for each coefficient against the corresponding reference power Pf(i) 505. This generates a binary masking matrix M(i):

$$M ( i ) = \{ \begin{matrix}1 , if P ( i ) > γ . {P}_{f} ( i ) \\ 0 , if P ( i ) \leq γ . {P}_{f} ( i )\end{matrix}$$

where γ is a pre-defined power spectral density factor.

The value M(i)=1 in the binary mask indicates that the corresponding coefficient P(i) is voice-like. In this case, there is no need to change the coefficient P(i). The value M(i)=0 indicates that the corresponding coefficient P(i) is noise-like. In this case, the corresponding coefficient should be adjusted using adaptive gain control 506,507.

In the example of FIG. 5a, adaptive gain control is composed of three operations.

In a first operation, an absolute hearing threshold (THD1) Th1(i) (i=0, 1, 2, . . . ) is provided for each frequency index (i=0, 1, 2, . . . ) 511. This threshold is set in dependence on how perceptible each spectral component is expected to be to a user. Each frequency can be associated with a respective power threshold THD1, which is determined by psychoacoustic principles. Above the threshold, a spectral component at that frequency will be perceptible to the human auditory system; otherwise, it will not be perceptible. THD1 can thus be pre-defined and can be provided as a look-up table to masking power generator 209.

In practice, an absolute hearing threshold does not necessarily need to be defined for each individual spectral component. Instead the SDFT coefficients can be divided into several groups, and all coefficients within the same group can be associated with the same absolute hearing threshold. In other words, Th1(i)=Th1(j) for any coefficient indices i, j that are part of the same respective group.

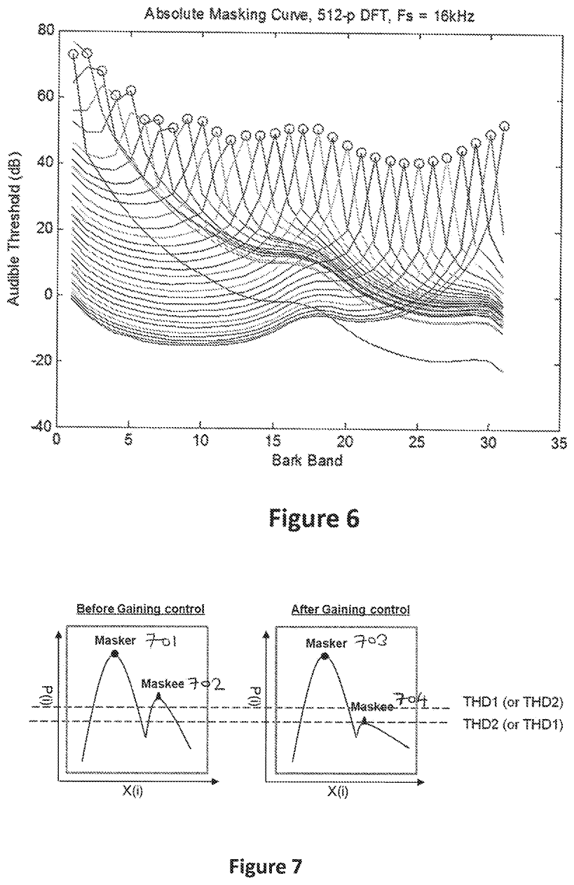

The set of SDFT coefficients is preferably divided into groups of coefficients that are adjacent to each other (i.e. the coefficients represent adjacent frequency bins and thus have adjacent indices). A simple approach is to uniformly divide the coefficients into N groups (e.g., N=30), where each group has the same number of SDFT coefficients. Alternatively, the groups may be concentrated at certain frequencies. The number of coefficients assigned to a particular group may be different for a low frequency group than for a high frequency group. A preferred approach is to use the so-called bark scale, which is similar to a log scale. This is consistent with the basics of psychoacoustics. In general, the number of coefficients in a low frequency group should be less than the number of coefficients in a high frequency group. The absolute hearing thresholds for different bark bands is shown in FIG. 6, which assumes 31 bark bands and a 16 kHz sampling rate.

In a second operation, a relative masking threshold (THD2) is estimated for each frequency index (i=0, 1, 2, . . . ) 513. THD2 can be set by considering the masking effect of different frequencies. THD2 is preferably not determined individually for each coefficient representing a frequency index i, but is instead determined for each group of frequency indices. The coefficients may be grouped together following any of the approaches described above. In each group, the coefficient that has the maximum power in the current group is set as the “masker” 512. THD2 may be set to the power of the masker minus some predetermined amount α, where α may be set according to the principles of psychoacoustics. A suitable value for the predetermined amount α might be 13 dB, for example.

The final masking threshold for each coefficient index is then selected to be the minimum of THD1 and THD2 514, i.e. THD(i)=min{THD1(i), THD2(i)}.

The third operation uses the binary mask determined in 505. For coefficients whose corresponding binary mask element is M(i)=1, the gain may be set to one, i.e. no change is made to that spectral component. For coefficients whose corresponding binary mask element is M(i)=0, the appropriate gain is determined by comparing the power determined for that spectral component in 504 with the threshold THD decided on in 514. This comparison is shown in block 515, and it can be expressed as follows:

$$g ( i ) = \{ \begin{matrix}1 , if P ( i ) < THD ( i ) \\ \frac{THD ( i )}{P ( i )} , if P ( i ) > THD ( i ) \end{matrix}$$

where g(i) is the adaptive gain.

Essentially, if P(i)<THD (i) the spectral component is too weak to be heard and gain control is not required. If if P(i)>THD (i) the spectral component is sufficiently strong to be heard and so its power is adjusted by applying an appropriate gain to its coefficient in the frequency domain. The adaptive gain control is applied in 508 by computing a new coefficient X′(i):

X′(i)=g(i)*X(i)

The new coefficients X′(i) (i=0, 1, 2, . . . ) form the basis for the inverse Fourier transform in 509 that constructs the output frame 510. In this example the adjusted and non-adjusted coefficients are combined in the frequency domain and are then transformed together into the time domain. The combination could equally take place after the transformation into the time domain, so that the adjusted and non-adjusted coefficients are transformed into the time domain separately and then combined together to form a single output frame.

In other implementations, the threshold THD(i) may be determined differently. For example, FIG. 5b shows an implementation in which the final threshold is set by the absolute threshold. In this example THD(i)=THD1(i) in 514 and it is unnecessary to calculate the relative masking threshold THD2. Another implementation is shown in FIG. 5c. in this example, the final threshold is set by the relative threshold. Therefore, THD(i)=THD2(i) in 514 and it is unnecessary to calculate the absolute masking threshold THD1. In this implementation, it is desirable to increase the power difference between masker and maskee to obtain a better masking effect so the predetermined amount by which the power of the masker is decremented is preferably increased. For example, a may be increased from 13 dB to 16 dB.

The coefficient-wise gain control described above changes the frequency domain spectrum and masks the noise components so that they become less perceptible. This effect is illustrated in FIG. 7. Masker 701 in the original signal (before gain control) belongs to a wanted component. Maskee 702 belongs to an unwanted component. After gain control, the power of masker 703 is unchanged, whereas the power of maskee 704 has been reduced (as demonstrated by the dashed lines). The relative power of the two components has thus been adjusted, with the effect that the wanted component has become more easily distinguishable over the unwanted component. This can be particularly useful in implementations where the input signal is a noisy speech signal, since the result is an enhanced signal with improved speech intelligibility. This enhanced signal can be used as a target signal in any multiple microphone speech enhancement technique.

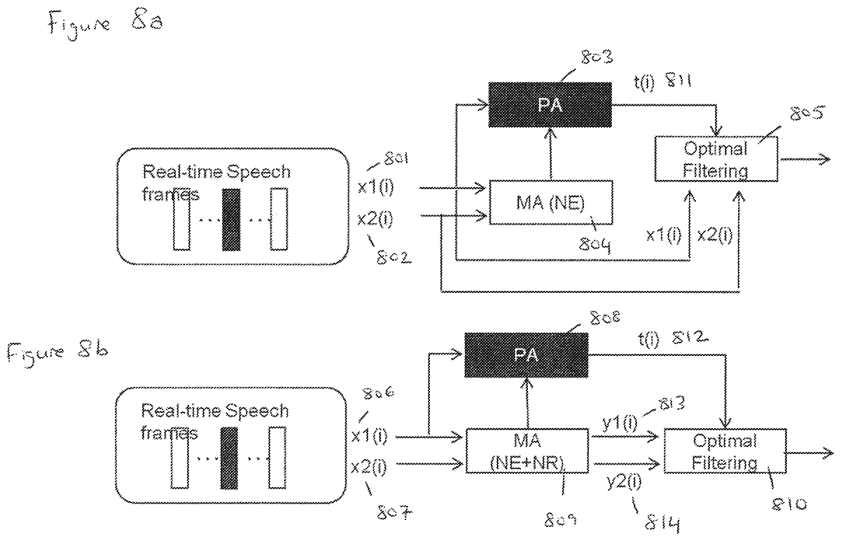

FIGS. 8a and b illustrate two examples of a system based on a multiple microphone array. In both these examples, the multiple microphone array has two microphones. This is solely for the purposes of example. It should be understood that the techniques described herein might be beneficially implemented in a system having any number of microphones, including systems based on single channel enhancement or systems having arrays with three or more microphones.

In FIGS. 8a and b, both systems are configured to receive real-time speech frames from two microphone signals: x1(i) and x2(i) (801, 802, 806, 807). Both systems have a perception analyser (PA) block 803, 808 that is configured to implement an enhancement technique in accordance with one or more of the embodiments described above. Each PA block outputs a target signal t(i) 811, 812. Each system also includes an optimal filtering block 805, 810. Each optimal filtering block is configured to implement an algorithm for filtering x1(i) and x2(i) subject to the constraint of the target signal t(i). any suitable algorithm might be used. For example, a generalized adaptive filtering algorithm could be based on the optimum filtering problem defined by:

min(∥Ã·X−Tλ²)

where X is a matrix expression of microphone signals x1(i) and x2(i) and T is a matrix expression of target signal t(i). The optimum filters parameters are defined by the matrix expression Ã The set of optimum filter parameters Ã can then be used to filter the microphone signals to generate a single, enhanced signal.

The primary aim in an ASR scenario is to increase the intelligibility of the audio signal that is input to the ASR block. The original microphone signals are optimally filtered. Preferably, no additional noise reduction is performed to avoid removing critical voice information. For a voice communication scenario, a good trade-off between subjective quality and intelligibility should be maintained. Noise reduction should be considered for this application. Therefore, the microphone signals may be subjected to noise reduction before being optimally filtered. These alternatives are illustrated in FIGS. 8a and b.

In FIG. 8a, the primary function of the microphone array (MA) processing block 804 is noise estimation (NE). It is configured to generate the reference power density of each coefficient. The target signal t(i) is generated in the PA block 803. The optimal filtering block 805 completes the speech enhancement process by filtering the microphone signals constrained by target signal, t(i).

In FIG. 8b, the primary function of MA block 809 is again noise estimation (NE). It is also configured to implement an appropriate noise reduction method (NR). This generates preliminary enhanced signals, y1(i) and y2(i) (813, 814). The target signal t(i) is generated in PA block 808. The optimal filtering block 810 completes the speech enhancement process by filtering the microphone signals constrained by target signal, t(i).

In the two-microphone arrangement shown in FIGS. 8a and b, either microphone signal can be used as the direct input to the PA blocks 803, 808. However, any other signal could also be used. For example, one of y1(i) and y2(i) can be used as the input to the PA block 803, 808. Another option is to deliberately pick a signal to achieve a particular effect. For example, a specific signal could be selected in order to implement beamforming, which aims to achieve further enhancements by considering the spatial correlation between different channels of microphone signals.

It should be understood that where this explanation and the accompanying claims refer to the device doing something by performing certain steps or procedures or by implementing particular techniques that does not preclude the device from performing other steps or procedures or implementing other techniques as part of the same process. In other words, where the device is described as doing something “by” certain specified means, the word “by” is meant in the sense of the device performing a process “comprising” the specified means rather than “consisting of” them.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present disclosure may consist of any such individual feature or combination of features. In view of the foregoing description it will be evident to a person skilled in the art that various modifications may be made within the scope of the disclosure.

What is claimed is:

1. A signal enhancer comprising:
an input configured to receive an audio signal that has a wanted component and an unwanted component;
a perception analyser configured to:
split the audio signal into a plurality of spectral components;
for each spectral component, designate that spectral component as belonging to the wanted component or the unwanted component in dependence on a power estimate associated with that spectral component; and
when that spectral component is designated as belonging to the unwanted component, adjust power associated with that spectral component by applying an adaptive gain to that spectral component, wherein the adaptive gain is selected in dependence on how perceptible the spectral component is expected to be to a user.

2. The signal enhancer according to claim 1, wherein the perceptual analyser is configured to, for each spectral component that is designated as belonging to the unwanted component, compare the power estimate with a power threshold;
if the power estimate is below the power threshold, select the adaptive gain to be a gain that will leave the power associated with that spectral component unchanged; and
if the power estimate is above the power threshold, select the adaptive gain to be a gain that will reduce the power associated with that spectral component.

3. The signal enhancer according to claim 2, wherein the power threshold is selected in dependence on power at which that spectral component is expected to become perceptible to the user.

4. The signal enhancer according to claim 2, wherein the power threshold is selected in dependence on how perceptible the spectral component is expected to be to the user given power associated with one or more of the other spectral components.

5. The signal enhancer according to claim 2, wherein the perception analyser is configured to select the power threshold for each spectral component in dependence on a group associated with that spectral component, wherein the same power threshold is applied to the power estimates for all the spectral components comprised in a specific group.

6. The signal enhancer according to claim 5, wherein the perception analyser is configured to select the power threshold for each group of spectral components to be a predetermined threshold that is assigned to that specific group in dependence on one or more frequencies that are represented by the spectral components in that group.

7. The signal enhancer according to claim 5, wherein the perception analyser is configured to determine the power threshold for a group of spectral components in dependence on the power estimates for the spectral components in that specific group.

8. The signal enhancer according to claim 7, wherein the perception analyser is configured to determine the power threshold for the specific group of spectral components by:
identifying highest power estimated for a spectral component in that specific group; and
generating the power threshold by decrementing the highest power by a predetermined amount.

9. The signal enhancer according to claim 5, wherein the perception analyser is configured to select the power threshold for the group of spectral components by comparing:
a first threshold, which is assigned to that specific group in dependence on one or more frequencies that are represented by the spectral components in that group; and
a second threshold, which is determined in dependence on the power estimates for the spectral components in that group;
the perception analyser is further configured to select, as the power threshold for the group, the lower of the first and second thresholds.

10. The signal enhancer according to claim 2, wherein the perception analyser is configured to, for each spectral component that is designated as: (i) belonging to the unwanted component; and (ii) having a power estimate that is above the power threshold, select the adaptive gain to be a ratio between the power threshold and the power estimate for that spectral component.

11. The signal enhancer according to claim 1, wherein the signal enhancer comprises a frequency transformer configured to:
receive the audio signal in a time domain and convert that signal into a frequency domain, whereby the frequency domain version of the audio signal represents each spectral component of the audio signal by a respective coefficient;
wherein the perception analyser is configured to adjust the power associated with a spectral component by applying the adaptive gain to the respective coefficient that represents that spectral component in the frequency domain version of the audio signal.

12. The signal enhancer according to claim 11, wherein the perception analyser is configured to form a target audio signal that comprises:
non-adjusted coefficients that represent the spectral components designated as belonging to the wanted component of the audio signal; and
adjusted coefficients that represent the spectral components designated as belonging to the unwanted component of the audio signal.

13. The signal enhancer according to claim 12, wherein the frequency transformer is configured to receive the target audio signal in the frequency domain and convert it into the time domain, wherein an output of the signal enhancer is configured to output the time domain version of the target audio signal.

14. A method, applied to a signal enhancer comprising an input and a perception analyser, the method comprising:
obtaining, by the input of the signal enhancer, an audio signal that has a wanted component and an unwanted component;
splitting, by the perception analyser of the signal enhancer, the audio signal into a plurality of spectral components;
for each spectral component, designating, by the perception analyser of the signal enhancer, that spectral component as belonging to the wanted component or the unwanted component in dependence on a power estimate associated with that spectral component; and
when that spectral component is designated as belonging to the unwanted component, adjusting, by the perception analyser of the signal enhancer, power associated with that spectral component by applying an adaptive gain to that spectral component, wherein the adaptive gain is selected in dependence on how perceptible the spectral component is expected to be to a user.

15. A non-transitory machine-readable storage medium having stored thereon processor-executable instructions, which when executed by a processor of a machine, cause the machine to implement a method comprising:
obtaining an audio signal that has a wanted component and an unwanted component;
splitting the audio signal into a plurality of spectral components;
for each spectral component, designating that spectral component as belonging to the wanted component or the unwanted component in dependence on a power estimate associated with that spectral component; and
when that spectral component is designated as belonging to the unwanted component, adjusting power associated with that spectral component by applying an adaptive gain to that spectral component, wherein the adaptive gain is selected in dependence on how perceptible the spectral component is expected to be to a user.

16. The method according to claim 14, further comprising:
for each spectral component that is designated as belonging to the unwanted component, comparing the power estimate with a power threshold;
if the power estimate is below the power threshold, selecting the adaptive gain to be a gain that will leave the power associated with that spectral component unchanged; and
if the power estimate is above the power threshold, selecting the adaptive gain to be a gain that will reduce the power associated with that spectral component.

17. The method according to claim 16, wherein the power threshold is selected in dependence on power at which that spectral component is expected to become perceptible to the user.

18. The method according to claim 16, wherein the power threshold is selected in dependence on how perceptible the spectral component is expected to be to the user given power associated with one or more of the other spectral components.

19. The non-transitory machine-readable storage medium according to claim 15, wherein the method further comprises:
for each spectral component that is designated as belonging to the unwanted component, comparing the power estimate with a power threshold;
if the power estimate is below the power threshold, selecting the adaptive gain to be a gain that will leave the power associated with that spectral component unchanged; and
if the power estimate is above the power threshold, selecting the adaptive gain to be a gain that will reduce the power associated with that spectral component.

20. The non-transitory machine-readable storage medium according to claim 19, wherein the power threshold is selected in dependence on power at which that spectral component is expected to become perceptible to the user.
